(19) United States
(12) Patent Application Publication
(10) Pub. No.: US 2007/0030503 A1
(43) Pub. Date: Feb. 8, 2007

(54) Image processing apparatus, image processing method, and computer product

(76) Inventor: Kazunari Tonami, Kanagawa (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/497,138

(22) Filed: Jul. 31, 2006

(30) Foreign Application Priority Data
Aug. 2, 2005 (JP) 2005-224286

(51) Int. Cl. G03F 3/08; G06F 15/00

(52) U.S. Cl. 358/1.9; 358/518; 358/3.27

(57) ABSTRACT

An image processing apparatus generates color signals corresponding to respective color materials for forming a color image using a grayscale color material for at least one of a plurality of colors based on image data. A color converting unit generates a color signal corresponding to each of the color materials from the image data. A feature detecting unit detects a feature of an image from the color signal corresponding to the grayscale color material generated by the color converting unit. A correcting unit corrects a color signal corresponding to the grayscale color material based on the feature of the image detected by the feature detecting unit.

### PRIORITY

The present application claims priority to and incorporates by reference the entire contents of Japanese priority document, 2005-224286, filed in Japan on Aug. 2, 2005.

### BACKGROUND OF THE INVENTION

1. Field of the Invention

The present invention relates to an image processing apparatus, an image processing method, and a computer product for executing the image processing method.

2. Description of the Related Art

Recent inkjet printers use low density inks (light inks) as a method of reducing granular texture of photographic images. This method reproduces an image using two types of inks, namely a dark one and light one having the same hue, for example, a light cyan ink and a cyan ink, and a light magenta ink and a magenta ink. Particularly, the use of a light ink in a low density area improves its granular texture to achieve a smooth photographic image.

The same method can be applied to electrophotography to improve the granular texture by using dark and light toners of the same hue. Japanese Patent Application Laid-open No. H8-171252 proposes an electrophotographic apparatus that forms an image using toners of five colors including light black, whose density is approximately a half the density of black, in addition to four colors of cyan, magenta, yellow, and black. In addition, Japanese Patent Application Laid-open No. 2001-290319 proposes an electrophotographic apparatus that uses dark and light toners.

Generally, an electrophotographic engine is disadvantageous in its difficulty in positional alignment of prints of individual colors and a large print misalignment over an image forming apparatus with a simple mechanism, such as an inkjet printer. When such an image forming apparatus that suffers a large print misalignment forms an image using both dark and light toners, as done in the technique of Japanese Patent Application Laid-open No. H8-171252, the formed image appears overlapped in its character portion and its line portion, and lacks sharpness. Even with an image forming apparatus that has less print misalignment, using only one of a dark toner and a light toner provides a sharper image for a character portion and a line portion rather than using both the dark and light toners. Accordingly, a technique of detecting the feature of an image and changing the ratio of dark and light toners in use based on the detected feature as done in Japanese Patent Application Laid-open No. 2001-290319 has been proposed.

FIG. 16 is a schematic diagram of one example of a separation table for changing ratios of dark and light toners in use according to a conventional technique. The ratio of dark and light toners in use is determined by the separation table. Separation tables 1501 and 1502 in FIG. 16 define the amount of dark and light black signals (Bk, Lk) to be output with respect to the amount of a black signal (K data) before separation. The separation table 1501 is for a relatively high use ratio of a light toner, and the separation table 1502 is for a relatively high use ratio of a dark toner.

Japanese Patent Application Laid-open No. 2001-290319 describes the configuration that determines whether an image is a halftone area or a character area, and generates dark and light image data by using a large amount of light toner for the halftone area in the separation table 1501 and using a large amount of dark toner for the character area in the separation table 1502. Even with the use of the separation table 1502, however, an image is formed by using both dark and light toners in an area A or an area A′ in FIG. 16, so that image degradation becomes noticeable at the time of print misalignment.

The configuration disclosed in Japanese Patent Application Laid-open No. 2001-290319 can use only a dark toner for a character area, which prevents the sharpness from being deteriorated at the time of print misalignment. As the image is formed with only the dark toner even for low density characters in this case, the benefit of using a light toner to improve the quality of low density characters cannot be acquired.

In other words, an optimal image cannot be acquired by the method of the conventional techniques that simply change the ratio of dark and light toners in use according to the feature of an image. According to the conventional techniques, the ratio of dark and light toners in use, as well as discrimination of a halftone area and a character area in an image is controlled. This increases the number of separation tables as shown in FIG. 16, leading to a problem of increase of hardware scale.

### SUMMARY OF THE INVENTION

The image processing apparatus, image processing method, and computer product are described. In one embodiment, an image processing apparatus that generates color signals corresponding to respective color materials for forming a color image using a grayscale color material for at least one of a plurality of colors based on image data, the image processing apparatus comprises a color converting unit to generate a color signal corresponding to each of the color materials from the image data, a feature detecting unit to detect a feature of an image from the color signal corresponding to the grayscale color material generated by the color converting unit, and a correcting unit to correct a color signal corresponding to the grayscale color material based on the feature of the image detected by the feature detecting unit.

### BRIEF DESCRIPTION OF THE DRAWINGS

FIG. 1 is an explanatory diagram of an image forming apparatus according to a first embodiment of the present invention;

FIG. 2 is a functional block diagram of an image processing apparatus included in the image forming apparatus according to the first embodiment;

FIG. 3A is a functional block diagram of a color converting unit;

FIG. 3B is an example of an amount of K signal generated with respect to an amount of Min(C0, M0, Y0);

FIG. 4 is an example of a separation table which a Bk/Lk separating unit uses to separate black to grayscale color materials;

FIG. 5 is a schematic diagram of an edge detecting filter used in an edge detecting unit;

FIG. 6A is an explanatory diagram of correction of a Bk signal and an Lk signal by a Bk/Lk correcting unit;

FIG. 6B is a flowchart of an image processing procedure according to the first embodiment;

FIG. 7 is a functional block diagram of an image processing apparatus according to a second embodiment of the present invention;

FIG. 8 is an example of a separation table used by the image processing apparatus according to the second embodiment;

FIG. 9 is an explanatory diagram of a correction operation for a Bk signal and an Lk signal in a Bk/Lk correcting unit in the image processing apparatus according to the second embodiment;

FIG. 10A is an explanatory diagram of a correction operation for a Bk signal and an Lk signal in other Bk/Lk correcting unit;

FIG. 10B is a flowchart of an image processing procedure according to the second embodiment;

FIG. 11 is a functional block diagram of an image processing apparatus according to a third embodiment of the present invention;

FIG. 12A is an explanatory diagram of a correction operation for a Bk signal and an Lk signal in a Bk/Lk correcting unit in the image processing apparatus according to the third embodiment;

FIG. 12B is a flowchart of an image processing procedure according to the third embodiment;

FIG. 13A is a functional block diagram of an image processing apparatus according to a fourth embodiment of the present invention;

FIG. 13B is a flowchart of an image processing procedure according to the fourth embodiment;

FIG. 14A is a functional block diagram of an image processing apparatus according to a fifth embodiment of the present invention;

FIG. 14B is a flowchart of an image processing procedure according to the fifth embodiment;

FIG. 15 is a block diagram of a hardware configuration of the image processing apparatus according to the present embodiments; and

FIG. 16 is a schematic diagram of one example of a separation table for changing a ratio of dark and light toners in use according to a conventional technique.

### DETAILED DESCRIPTION OF THE PREFERRED EMBODIMENTS

One or more embodiments of the present invention at least partially solve the problems described above in the conventional technology.

An image processing apparatus according to one embodiment of the present invention generates color signals corresponding to respective color materials for forming a color image using a grayscale color material for at least one of a plurality of colors based on image data. The image processing apparatus includes a color converting unit that generates a color signal corresponding to each of the color materials from the image data; a feature detecting unit that detects a feature of an image from the color signal corresponding to the grayscale color material generated by the color converting unit; and a correcting unit that corrects a color signal corresponding to the grayscale color material based on the feature of the image detected by the feature detecting unit.

An image processing apparatus according to another embodiment of the present invention generates color signals corresponding to respective color materials for forming a color image using a grayscale color material for at least one of a plurality of colors based on image data. The image processing apparatus includes a feature detecting unit that detects a feature of an image from the image data; a color converting unit that generates a color signal corresponding to each of the color materials from the image data; and a correcting unit that corrects a color signal corresponding to a grayscale color material generated by the color converting unit, based on the feature of the image detected by the feature detecting unit.

An image processing method according to still another embodiment of the present invention generates color signals corresponding to respective color materials for forming a color image using a grayscale color material for at least one of a plurality of colors based on image data. The image processing method includes generating a color signal corresponding to each of the color materials from the image data; detecting a feature of an image from the color signal corresponding to the grayscale color material generated at the generating; and correcting a color signal corresponding to the grayscale color material based on the feature of the image detected at the detecting.

The above and other embodiments, features, advantages and technical and industrial significance of this invention will be better understood by reading the following detailed description of presently preferred embodiments of the invention, when considered in connection with the accompanying drawings.

Exemplary embodiments of the present invention will be explained below in detail with reference to the accompanying drawings.

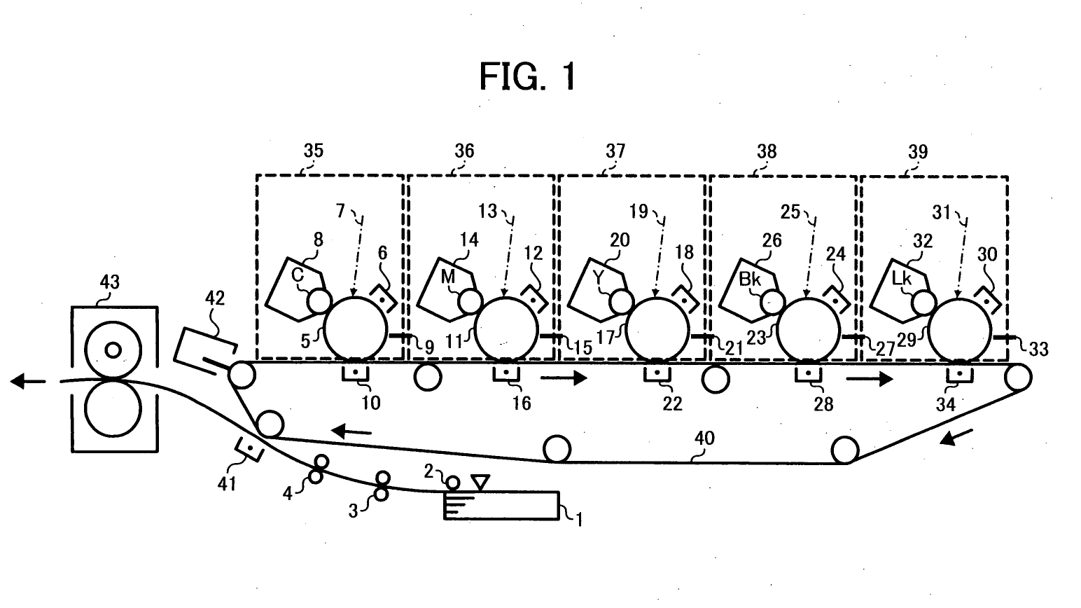

FIG. 1 is an explanatory diagram of an image forming apparatus according to the first embodiment. The image forming apparatus is explained as a color image forming apparatus.

The image forming apparatus includes image forming stations 35 to 39, photoconductors 5, 11, 17, 23, 29, chargers 6, 12, 18, 24, 30, exposure beams 7, 13, 19, 25, 31, developing units 8, 14, 20, 26, 32, cleaning blades 9, 15, 21, 27, 33, first transfer chargers 10, 16, 22, 28, 34, an intermediate transfer belt 40, a second transfer belt 41, an intermediate transfer cleaner 42, a fixing unit 43, a sheet feeding roller 2, a carrying roller pair 3, and a registration roller pair 4.

A recording sheet 1 is fed out one by one by the sheet feeding roller 2, and fed to the carrying roller pair 3. The carrying roller pair 3 feeds the recording sheet 1 to the registration roller pair 4. The registration roller pair 4 is so configured as to freely control the rotation and stopping of the rollers by a registration clutch (not shown), and temporarily stops the recording sheet 1 at the registration roller pair 4 to wait until a sequence of image forming processes (described later) is completed.

The image forming station 35 for cyan printing is indicated by reference numeral 35, and encircled by the dotted line in FIG. 1. The charger 6, the exposure beam 7, the developing unit 8, the cleaning blade 9, and the first transfer charger 10 are disposed around the photoconductor 5 to perform a sequence of image forming operations. A writing unit (not shown) irradiates the exposure beam 7 to the top surface of the photoconductor 5 charged uniformly by the charger 6, thereby forming a latent image on the photoconductor 5.

The developing unit 8 develops a cyan toner on the latent image on the photoconductor 5 to yield a visible toner image. The toner image is transferred onto the intermediate transfer belt 40 by the first transfer charger 10. The toner remaining on the photoconductor 5 is scraped off by the cleaning blade 9. The photoconductor 5 is charged again by the charger 6, after which the image forming operation is repeated.

The image forming station 36 for magenta printing is indicated by reference numeral 36, and encircled by the dotted line. The image forming station 36 has a configuration similar to that of the image forming station 35, and forms a magenta print and transfers a toner image for the magenta print onto the intermediate transfer belt 40 through a similar operation. The image forming stations 37, 38, 39 for yellow printing, dark black printing, and light black printing likewise transfer respective toner images onto the intermediate transfer belt 40.

After toner images of all the colors are transferred onto the intermediate transfer belt 40, the recording sheet 1 that has been halted and is waiting at the registration roller pair 4 is fed out at a matched timing, and toners of all the colors are transferred onto the recording sheet 1 by the second transfer belt 41. The recording sheet 1 is then fed to the fixing unit 43 where heat and pressure are applied to the recording sheet 1 so that unfixed toners are fixed on the recording sheet 1. The residual toners on the intermediate transfer belt 40 are scraped off as the intermediate transfer cleaner 42 abuts on the belt, thus cleaning the intermediate transfer belt 40.

Black is separated into dark black and light black. A black print is created by controlling the ratio of dark black and light black according to image data. For the image of a character area, in particular, when print misalignment occurs, out of color registration is caused noticeably due to the nature of a black color and characters. Such a problem is overcome by controlling the ratio of two blacks, namely dark black and light black, according to image data. However, the color separation is not only limited to black, and can be adapted to separation of other colors.

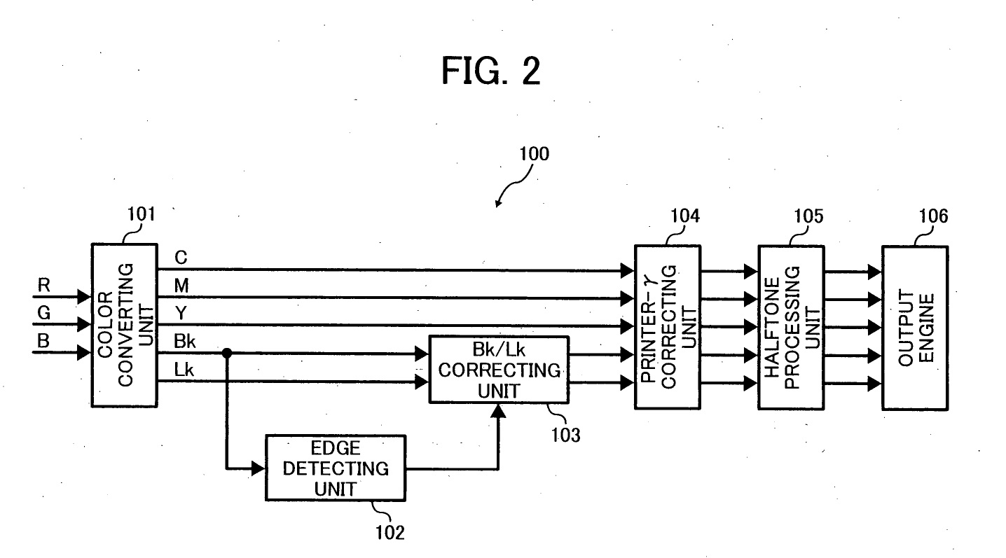

FIG. 2 is a functional block diagram of an image processing apparatus included in the image forming apparatus according to the first embodiment. An image processing apparatus 100 executes the image processing function in the image forming apparatus. The image processing apparatus 100 creates and sends image data to the writing unit (not shown). According to the image data sent from the image processing apparatus 100, the writing unit irradiates the exposure beam 7 to the photoconductor 5 to form a latent image on the top surface the photoconductor 5.

The image processing apparatus 100 includes a color converting unit 101, an edge detecting unit 102, a Bk/Lk correcting unit 103, a printer-γ correcting unit 104, a halftone processing unit 105, and an output engine 106. Red-Green-Blue (RGB) data can be input by an image inputting device like a scanner (not shown) or can be generated by interpreting a print command sent from a computer.

A digital color image signal input from the scanner (not shown) of the image forming apparatus is subject to ordinary scanner y correction, masking and filtering.

Data of a page description language (PDL) input from a host computer (not shown) connected to the image forming apparatus is developed into a two-dimensional bit map image for outputting characters and figures, which have been subject to an image developing process and represented by PDL commands, to a printer unit.

Image signals corrected and image signals developed from the PDL in this way are temporarily stored in a memory (not shown) via a selector, and are read out again to be input as RGB data to the color converting unit 101.

The color converting unit 101 converts the input RGB data to color signals corresponding to the color materials used by the output engine, namely, cyan, magenta, yellow, dark black, and light black (hereinafter C, M, Y, Bk, and Lk).

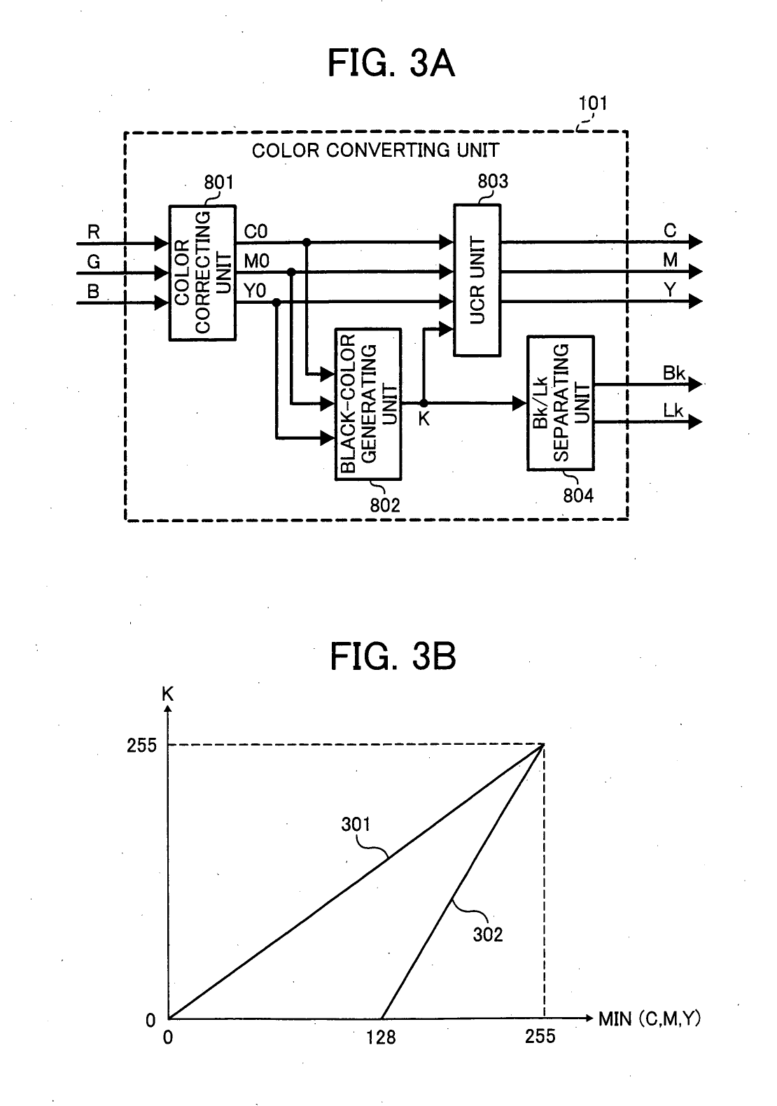

FIG. 3A is a functional block diagram of the color converting unit 101. The color converting unit 101 includes a color correcting unit 801, a black-color generating unit 802, an under-color-removal (UCR) unit 803, and a Bk/Lk separating unit 804. The color converting unit 101 converts an RGB signal as a standard signal to device-dependent signals corresponding to the color materials of the output engine 106. As the output engine 106 is configured to reproduce an image using toners of five colors, namely, cyan (C), magenta (M), yellow (Y), dark black (Bk), and light black (Lk), and as mentioned above, the color converting unit 101 accordingly performs color separation to the five colors of C, M, Y, K, Bk, and Lk.

The output of the color converting unit 101 is subject to γ characteristic conversion through table conversion in the printer-γ correcting unit 104, is then subject to a predetermined dithering process in the halftone processing unit 105, and is output to the output engine 106.

The operation of the color converting unit 101 is explained in detail with reference to FIG. 3A. As shown in FIG. 3A, the color converting unit 101 includes the color correcting unit 801, the black-color generating unit 802, the UCR unit 803, and the Bk/Lk separating unit 804. The standard signal RGB input to the color converting unit 101 is converted to a device-dependent CMY image signal in the color correcting unit 801. While there can be various methods for color correction, the following masking computation is performed in the present embodiment.
C0=c11×R+c12×G+c13×B+c14
M0=c21×R+c22×G+c23×B+c24
Y0=c31×R+c32×G+c33×B+c34
where c11 to c34 are predetermined color correction coefficients to output an 8-bit signal for CMY with respect to an image signal of 8 bits (0 to 255) for each of RGB.

The image signal from the color correcting unit 801 is input to the black-color generating unit 802, which generates a K signal. The K signal is given by the following expressions using a black generation parameter ax and a black color start point Thr1.
When Min(C0, M0, Y0)>Thr1, K=α×(Min(C0, M0, Y0)−Thr1)
When Min(C0, M0, Y0)=Thr1, K=0

The black color generation ratio can be controlled by the black color generation parameter α and the black color start point Thr1.

FIG. 3B is an example of the amount of the K signal generated with respect to the amount of Min(C0, M0, Y0). A line 301 in FIG. 3B is set such that the ratio of black color which starts at Min(C0, M0, Y0)=0 is high, and a line 302 in FIG. 3B is set such that the ratio of a black color which starts at Min(C0, M0, Y0)=128 is low. As the line 301 means black color covers over the entire range of Min(C0, M0, Y0) in the embodiment, the line is called a ratio of 100% black color generation, whereas as the line 302 means black color covers 50% of the entire range of Min(C0, M0, Y0) in the embodiment, the line is called a ratio of 50% black color generation.

At the UCR unit 803 generates C, M, and Y signals which has a black color component subtracted based on the C0, M0, and Y0 signals and the K signal generated in the black-color generating unit 802. The C, M, and Y signals are given by the following equations using a black color generation parameter β.
C=C0−β×K
M=M0−β×K
Y=Y0−β×K

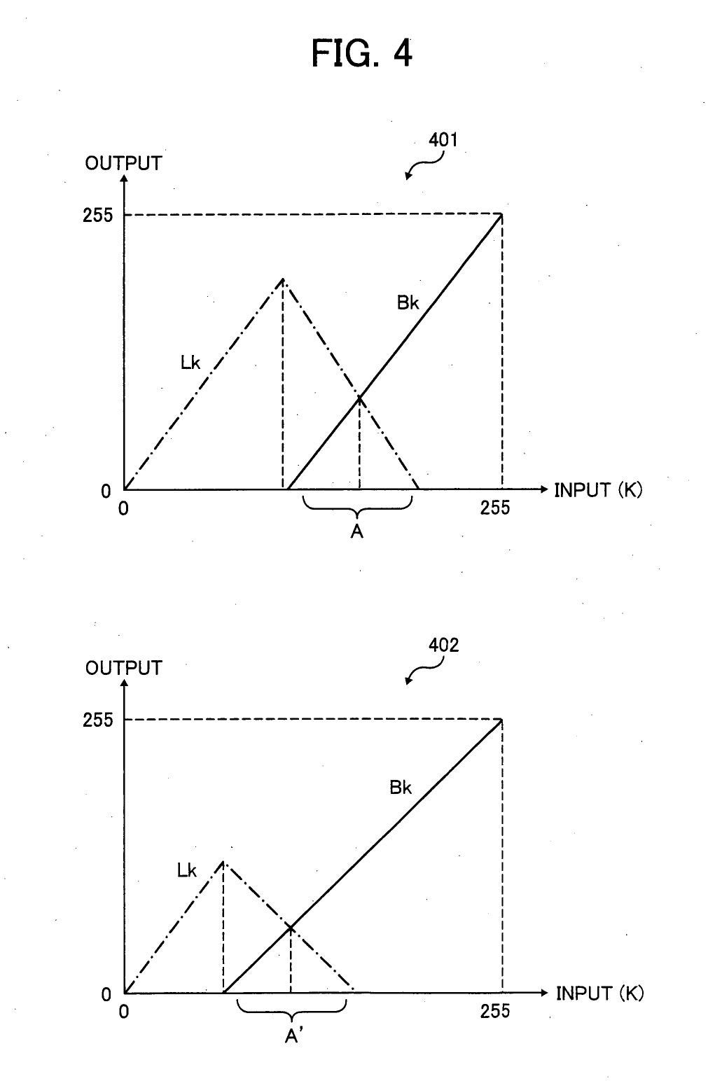

FIG. 4 is an example of the separation table which the Bk/Lk separating unit 804 uses to separate black to grayscale color materials. The Bk/Lk separating unit 804 generates the Bk and Lk signals from the K signal using a separation table 401 and a separation table 402 shown in FIG. 4.

The color converting unit 101 can use a color converting method called a direct mapping method, besides the configuration shown in FIG. 3A. The direct mapping method includes lattice points provided at color solids between spaces of RGB, includes transformation points from RGB to CMYBkLk on the lattice points as a look-up table (LUT), and directly calculates CMYBkLk from a plurality of lattice points near the input RGB data by an interpolation.

The edge detecting unit 102 detects an edge from the Bk signal in the output signals from the color converting unit 101.

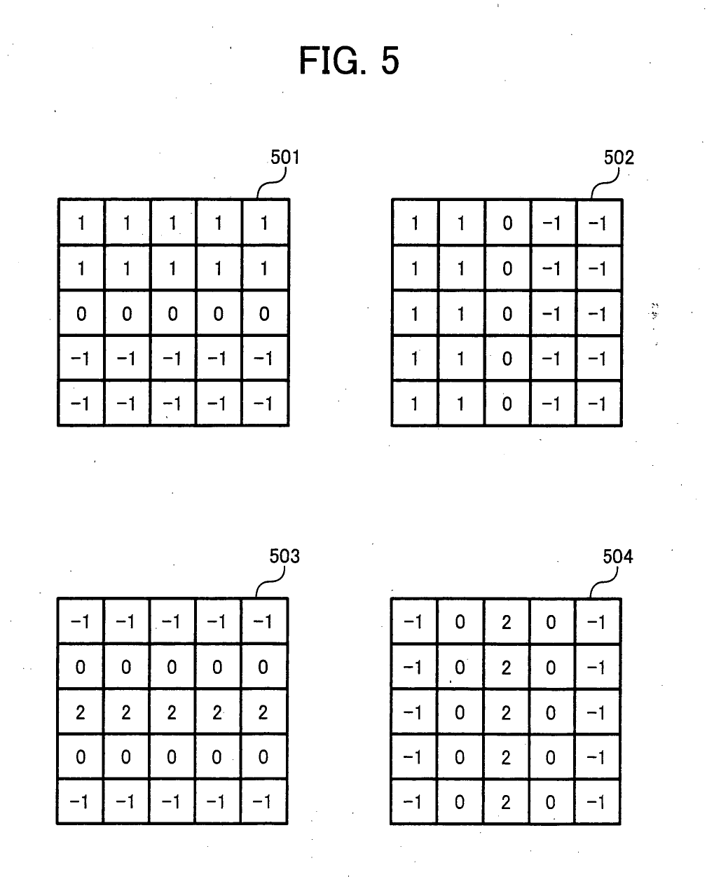

FIG. 5 is a schematic diagram of an edge detecting filter used in the edge detecting unit 102. Filters 501 and 502 detect the edges of a horizontal line and a vertical line, respectively. Filters 503 and 504 detect the ridges of a horizontal line and a vertical line, respectively. It is determined as an edge when the maximum value of the output values of the four edge detecting filters is equal to or greater than a predetermined threshold, while it is determined as a non-edge when the maximum value is less than the threshold. The edge detection result is sent to the Bk/Lk correcting unit 103.

The edge detecting method in the edge detecting unit 102 is not limited to the method mentioned above, and other methods can be also used. For example, the maximum value and the minimum value within a predetermined area (for example, 5×5 pixels) can be acquired and edge detection can be performed by checking if the difference therebetween is equal to or greater than a predetermined threshold.

The Bk/Lk correcting unit 103 calculates a correction amount δ given by the following equations with respect to the detected edge portion, corrects the Bk signal and the Lk signal using the correction amount δ, and outputs the signals. The corrected Bk signal and Lk signal are hereinafter denoted by Bk′ and Lk′, respectively.
Correction amount δ=Min(Lk×ε, 255−Bk)
where ε=light black toner density/dark black toner density.
Bk′=Bk+δ
Lk′=Lk−δ×(1/ε)
That is, correction is performed such that Lk is decreased within the range where Bk does not exceed 255, and the amount of Bk equivalent to the reduced amount of Lk is added to Bk.

The printer-γ correcting unit 104 performs γ correction on the CMY signal output from the color converting unit 101 and the Bk′ and Lk′ signals output from the Bk/Lk correcting unit 103, and the halftone processing unit 105 performs a halftone process thereto, and sends the resultant signals to the output engine 106 to output an image.

In the case that the Bk/Lk separating unit 804 of the color converting unit 101 uses the separation table 401 shown in FIG. 4, when low density data is input, the Lk signal alone has a value, and the Bk signal of 0 is output. When high density data is input, the Bk signal alone has a value, and the Lk signal of 0 is output. When intermediate density data indicated by “A” is input, both the Lk signal and the Bk signal having values are output.

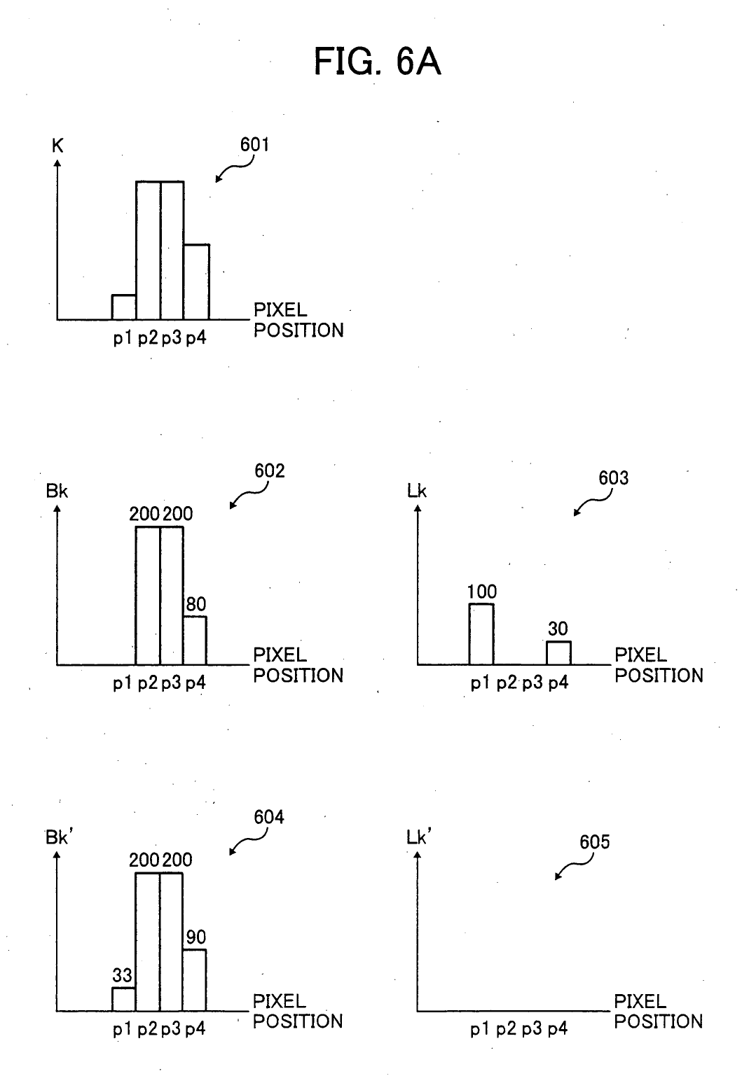

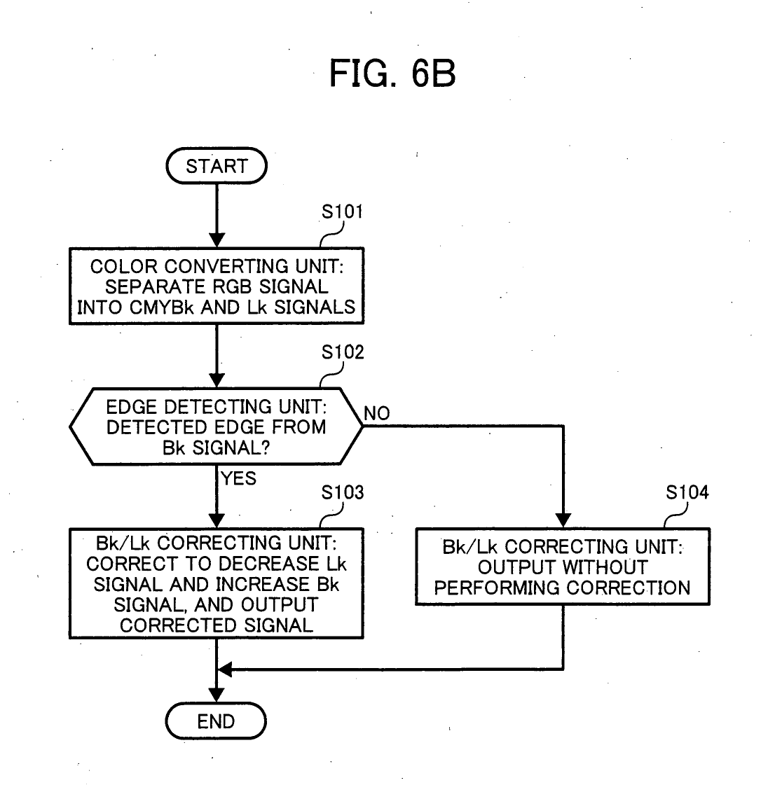

FIG. 6A is an explanatory diagram of correction of the Bk signal and the Lk signal by the Bk/Lk correcting unit 103. The horizontal axes of graphs 601 to 605 represent pixel positions expressed one-dimensionally. The graph 601 is the K signal when a high density line image having a width of 2 dots to 3 dots or the like is scanned by the scanner. The K signal is a signal before separation to the Bk signal and the Lk signal. While pixels at p2 and p3 take high density data values, pixels at p1 and p4 are scanned with the edge portions blurred and thus take low/intermediate density data values.

The graphs 602 and 603 respectively indicate the Bk signal and the Lk signal which are separated from the K signal and output from the color converting unit 101. The Bk signal alone takes a value for the pixel positions p2, p3 of high density input data, the Lk signal alone takes a value for the pixel position p1 of low density input data, and both the Bk signal and the Lk signal take values for the pixel positions p4 of intermediate density input data. Values in the graphs 602 and 603 indicate output values of the Bk signal and the Lk signal. The values are determined by the separation table 401 in FIG. 4, which depicts one example of the signals to be determined.

As apparent from the shape of the graph 602 in FIG. 6A, when edge detection from the Bk signal is performed, the image is determined to be an edge, so that the correction is performed on both the Bk signal and the Lk signal. With the ratio ε of the Lk toner density and the Bk toner density being ⅓, values of the corrected signals Bk′ and Lk′ become as indicated by the graphs 604 and 605 in FIG. 6A. That is, only the Bk signal takes a value while the Lk signal is 0 for all the pixels at p1 to p4.

FIG. 6B is a flowchart of an image processing procedure in the first embodiment. First, the color converting unit 101 separates the RGB signal to the CMYBk and Lk signals. At this time, the black-color generating unit 802 generates a black color using the table shown in FIG. 3B, and the Bk/Lk separating unit 804 separates the K signal into the Bk signal and the Lk signal (step S101).

The edge detecting unit 102 detects if the Bk signal separated by the Bk/Lk separating unit 804 is an edge (step S102). When the edge detecting unit 102 detects that it is an edge (step S102: Yes), the Bk/Lk correcting unit 103 performs correction so as to decrease the Lk signal and increase the Bk signal, and outputs the signals. The correction is the same as explained with reference to FIG. 6A (step S103).

When the edge detecting unit 102 does not detect an edge (step S102: No), the Bk/Lk correcting unit 103 directly sends the separated signals converted by the color converting unit 101 without performing correction to the output engine 106 (step S104).

When an image with the signals in the statuses of the graphs 602 and 603 in FIG. 6A is output without correcting the Bk and Lk signals in this way, the edge portions overlap if the output engine 106 causes misalignment of the Bk print and the Lk print, yielding an image with deteriorated sharpness. However, when correction by the image processing apparatus according to the first embodiment is performed, the correction process by the Bk/Lk correcting unit 103 can allow a high density line image to be formed using only the Bk toner, so that even when misalignment of the Bk print and the Lk print occurs, deterioration of the sharpness of the image can be prevented.

In the first embodiment, when a low density line image is input, the edge detecting unit 102 does not detect the line image as an edge, so that only the Lk signal in the output from the color converting unit 101 has a value and the Bk signal of 0 is output. Therefore, no edge is detected from the Bk signal, and no correction is performed. That is, as a low density line image is formed only with the Lk toner, a high quality image can also be acquired for a low density line image.

The image processing apparatus according to the first embodiment is configured such that the edge detecting unit 102 determines whether it is an edge or a non-edge, and the Bk/Lk correcting unit 103 calculates the correction amount δ for an edge portion and corrects the Bk signal and the Lk signal using the calculated correction amount δ. To minimize the deterioration of the image quality when the edge detecting unit 102 erroneously detects an edge, a first modification according to the first embodiment is configured such that the edge level is determined in multiple levels, not just binary determination of an edge or a non-edge, in correcting the Bk signal and the Lk signal. Because the functional block diagram of the image processing apparatus of the first modification is the same as that of FIG. 1, the illustration thereof is omitted.

As in the first embodiment, the maximum value of the output values of the edge detecting filters 501 to 504 in FIG. 5 is acquired for the Bk signal. The acquired maximum value is quantized into five levels using predetermined four thresholds to determine the edge level (hereinafter denoted by EdgeLevel). There are five EdgeLevels of 0, ¼, 2/4, ¾, and 1, and EdgeLevel=1 represents a maximum edge while EdgeLevel=0 represents a non-edge.

The Bk/Lk correcting unit 103 calculates the correction amount δ given by the following equations using the EdgeLevel, corrects the Bk signal and the Lk signal using the calculated correction amount δ, and outputs the signals.
Correction amount δ=Min(Lk×ε×EdgeLevel, 255−Bk)
Bk′=Bk+δ
Lk′=Lk−δ×(1/ε)

For an area with the maximum edge having EdgeLevel=1, the same correction as done in the first embodiment is performed. As the correction amount δ becomes 0 for a non-edge portion with EdgeLevel=0, substantially no correction is performed. Because correction according to the edge level is performed at an intermediate edge level (EdgeLevel=¼, 2/4, ¾), deterioration of the image quality when an edge is erroneously detected can be suppressed more as compared with the binary determination of an edge and a non-edge as performed in the case according to the first embodiment.

When the edge level is set in multiple levels as in the configuration of the first modification, the conventional technique (Japanese Patent Application Laid-open No. 2001-290319) increases the number of tables for calculating the ratio of dark and light toners, leading to the increase of the hardware scale, whereas the configuration of the first modification does not require multiple tables, making it possible to suppress the increase of the hardware scale.

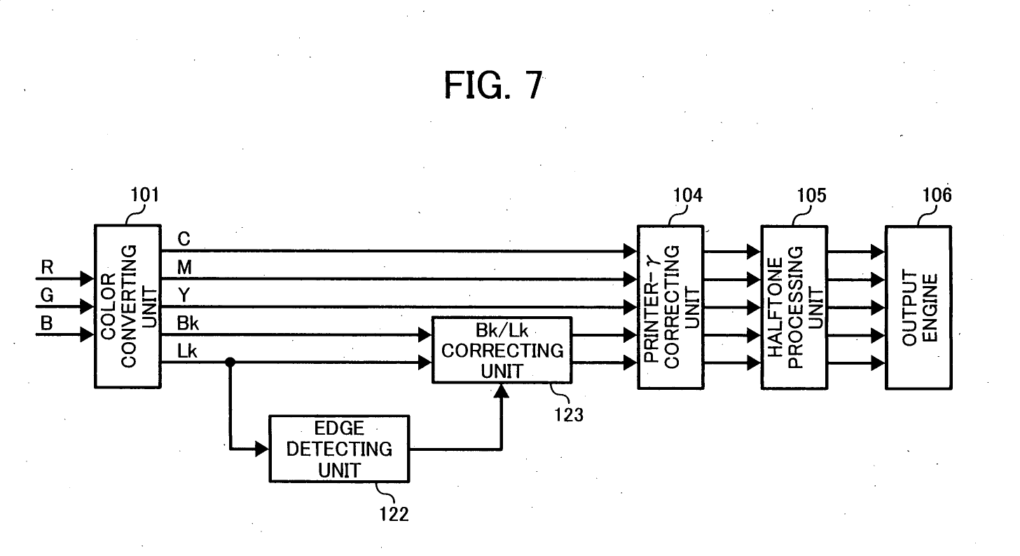

FIG. 7 is a functional block diagram of an image processing apparatus according to the second embodiment. Those components of the second embodiment that have the same reference numerals as the corresponding components according to the first embodiment execute the same functions, and their explanations will be omitted or simplified, while components with different reference numerals will be explained. The image processing apparatus according to the second embodiment includes an edge detecting unit 122 and a Bk/Lk correcting unit 123. The image processing apparatus according to the second embodiment differs from that according to the first embodiment in that the edge detecting unit 122 performs edge detection from the Lk signal in the output signals of the color converting unit 101.

The edge detecting unit 122 determines from the Lk signal whether it is an edge or a non-edge using the edge detecting filters 501 to 504 shown in FIG. 5, as performed in the case according to the first embodiment.

The Bk/Lk correcting unit 123 calculates a correction amount δ given by the following equations with respect to the detected edge portion, corrects the Bk signal and the Lk signal using the correction amount δ, and outputs the signals.
Correction amount δ=Min((Lk−Bk)×ε, 255−Bk)
Bk′=Bk+δ
Lk′=Lk−δ×(1/ε)−Bk

Finally, the printer-γ correcting unit 104 performs γ correction on the CMY signal output from the color converting unit 101 and the Bk′ and Lk′ signals output from the Bk/Lk correcting unit 123, and the halftone processing unit 105 performs a halftone process thereto, and sends the resultant signals to the output engine 106 to output an image.

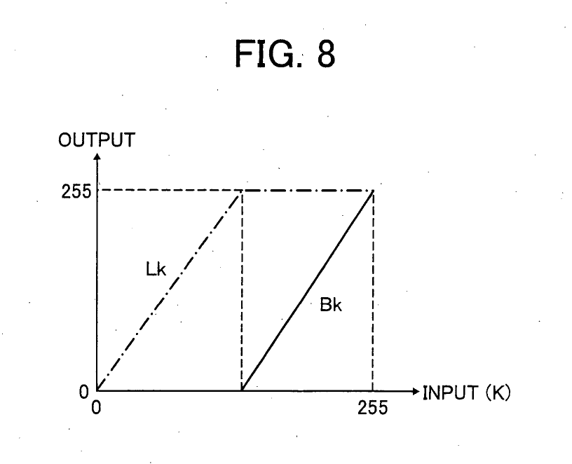

FIG. 8 is an example of a separation table used by the image processing apparatus according to the second embodiment. It is assumed that the separation table shown in FIG. 8 is used in the Bk/Lk separating unit 804 of the color converting unit 101. Unlike the separation table in FIG. 4, the separation table in FIG. 8 is for forming a high density image using both dark and light toners. In this case, when low density data is input, the Lk signal alone has a value and the Bk signal of 0 is output, whereas when high density data is input, both the Lk signal and the Bk signal have values.

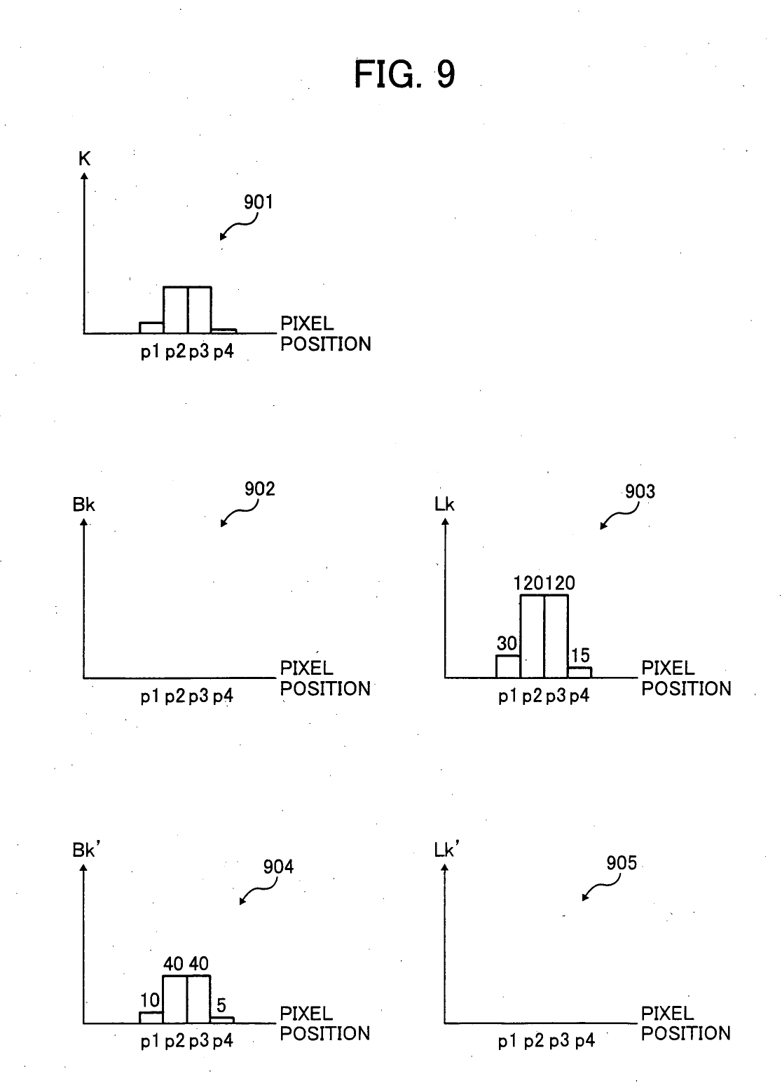

FIG. 9 is an explanatory diagram of a correction operation for the Bk signal and the Lk signal in the Bk/Lk correcting unit 123 in the image processing apparatus according to the second embodiment. The horizontal axes of graphs 901 to 905 represent pixel positions expressed one-dimensionally, as in FIG. 6A. The graph 901 is the K signal when a low density line image having a width of approximately 2 dots to 3 dots is scanned by the scanner. The K signal is a signal before separation to the Bk signal and the Lk signal. While pixels at p2 and p3 take high density data values, pixels at p1 and p4 are scanned with the edge portions blurred and thus take low/intermediate density data values.

The graphs 902 and 903 indicate the Bk signal and the Lk signal that are output from the color converting unit 101 with respect to the signals input from the graph 901. As the K signal which is input as indicated by the graph 901 has a low density, the Lk signal alone takes a value after color conversion (graph 903).

As apparent from the shape of the signal of the graph 903, edge detection from the Lk signal is performed, and the image is determined as an edge. Therefore, the correction is performed on the Bk signal and the Lk signal. When the ratio e of the Lk toner density and the Bk toner density is set to ⅓, values of the corrected signals Bk′ and Lk′ become as indicated by the graphs 904 and 905 in FIG. 9. That is, only the Bk′ signal takes a value while the Lk′ signal is 0.

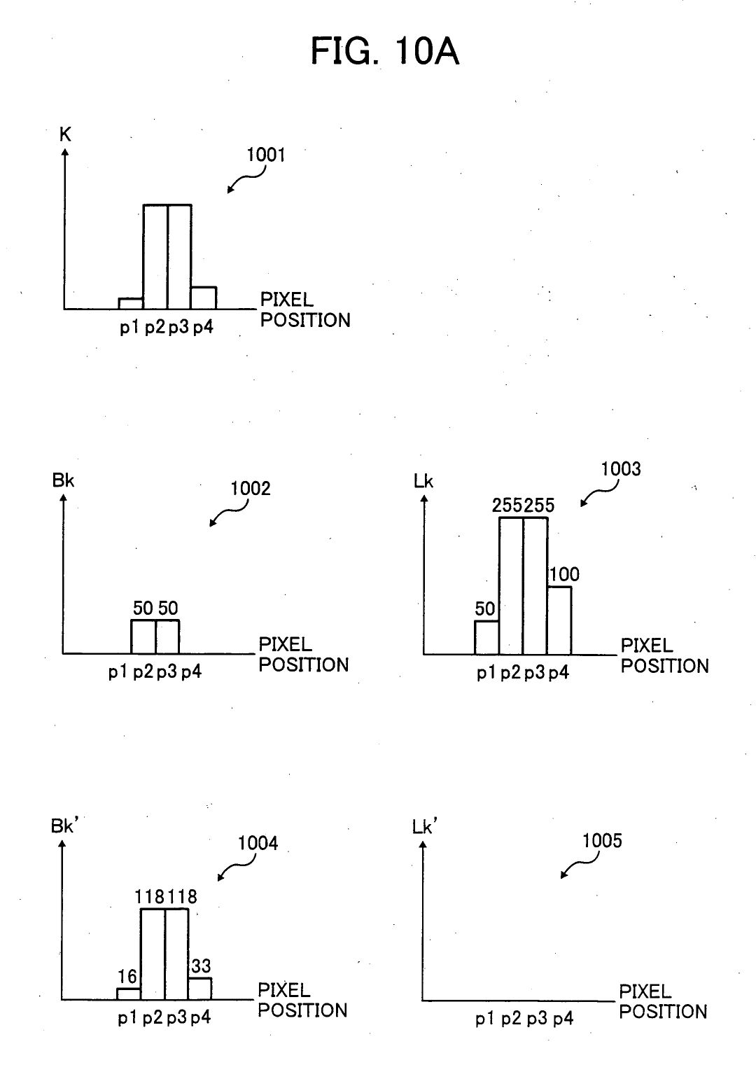

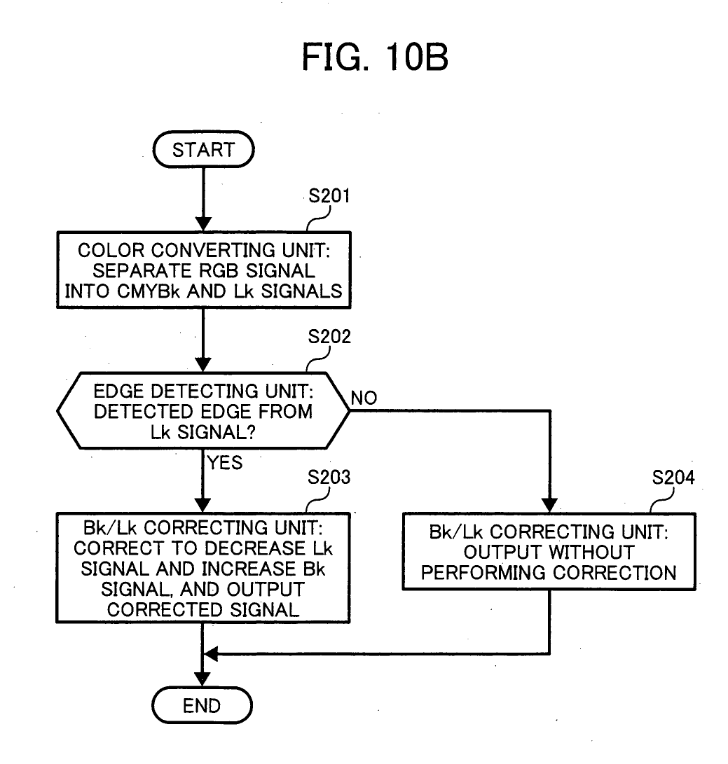

FIG. 10A is an explanatory diagram of a correction operation for the Bk signal and the Lk signal in other Bk/Lk correcting unit 123. A graph 1001 indicates an input signal (K signal) when an intermediate density line image having a width of approximately 2 dots to 3 dots is scanned by the scanner, and graphs 1002 and 1003 in FIG. 10A indicate the Bk signal and the Lk signal output from the color converting unit 101 with respect to the K input of graph 1001. As pixel positions p2, p3 have intermediate densities, the Lk signal and the Bk signal both have values after color conversion. As pixel positions p1, p4 have low densities, only the Lk signal has a value after color conversion.

As the Lk signal of the graph 1003 in FIG. 10A is determined as an edge, the correction is likewise performed on the Bk signal and the Lk signal. Values of the corrected signals Bk′ and Lk′ become as indicated by graphs 1004 and 1005 in FIG. 10A, and only the Bk signal has a value with the Lk signal being 0.

FIG. 10B is a flowchart of an image processing procedure in the second embodiment. First, the color converting unit 101 separates the RGB signal into the CMYBk and Lk signals. At this time, the black-color generating unit 802 generates black color using the table shown in FIG. 3B, and the Bk/Lk separating unit 804 separates the K signal into the Bk signal and the Lk signal (step S201).

The edge detecting unit 122 detects if the Bk signal separated by the Bk/Lk separating unit 804 is an edge (step S202). When the edge detecting unit 122 detects that it is an edge (step S202: Yes), the Bk/Lk correcting unit 123 performs correction such as to decrease the Lk signal and increase the Bk signal, and outputs the signals. The correction is the same as explained with reference to FIGS. 9 and 10A (step S203).

When the edge detecting unit 122 does not detect an edge (step S202: No), the Bk/Lk correcting unit 103 directly sends the separated signals converted by the color converting unit 101 without performing correction to the output engine 106 (step S204).

Likewise, correcting the Bk signal and the Lk signal can permit a high density line image to be corrected so that only the Bk signal has a value (not shown). In other words, line images whose densities range from a low density to a high density are formed with the Bk toner alone, deterioration of sharpness can be prevented even when print misalignment between a Bk print and an Lk print occurs.

Particularly, to form a low density line image only with the Bk toner, the low density line image can easily be determined as an edge by detecting an edge from the Lk signal as done in the present embodiment.

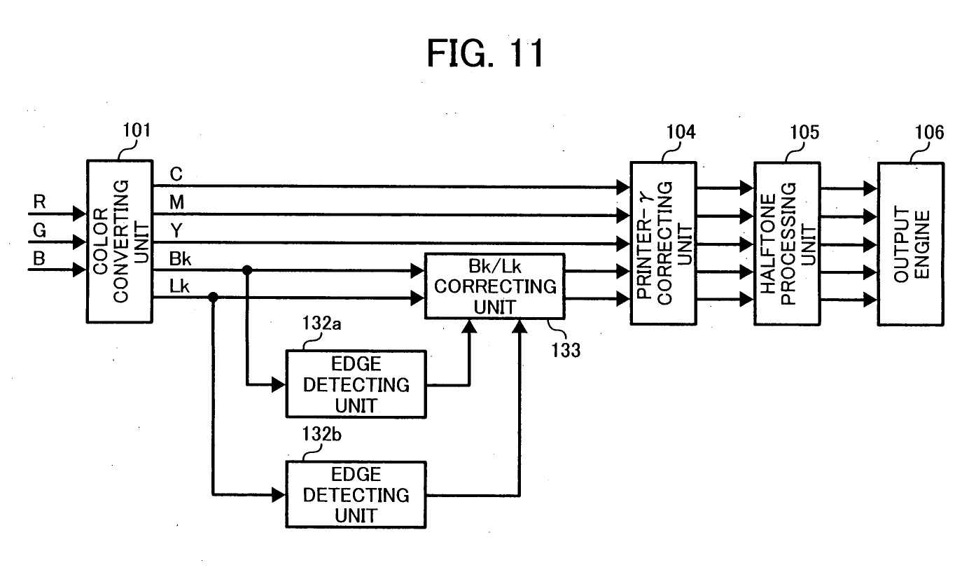

FIG. 11 is a functional block diagram of an image processing apparatus of the third embodiment. The image processing apparatus of the third embodiment includes an edge detecting unit 132a and an edge detecting unit 132b. The edge detecting unit 132a detects an edge from the Bk signal in the output signals of the color converting unit 101. The edge detecting unit 132b detects an edge from the Lk signal in the output signals of the color converting unit 101.

First, the edge detecting unit 132a acquires the maximum value of the output values of the edge detecting filters 501 to 504 in FIG. 5 for the Bk signal. The acquired maximum output value is then quantized into five levels using predetermined four thresholds to determine the edge level (hereinafter denoted by EdgeLevel_Bk). There are five EdgeLevels_Bk of 0, ¼, 2/4, ¾, and 1, and EdgeLevel_Bk=1 represents a maximum edge while EdgeLevel_Bk=0 represents a non-edge.

Likewise, the edge detecting unit 132b acquires five edge levels EdgeLevel_Lk for the Lk signal.

A Bk/Lk correcting unit 133 calculates a correction amount δ given by the following equations using the acquired EdgeLevel_Bk and EdgeLevel_Lk, corrects the Bk signal and the Lk signal using the calculated correction amount δ, and outputs the signals.
When EdgeLevel_Bk≧EdgeLevel_Lk,
Correction amount δMin((Lk×ε×EdgeLevel_{—}Bk, 255−Bk)
Bk′=Bk+δ
Lk′=Lk−δ×(1/ε)
When EdgeLevel_Bk<EdgeLevel_Lk,
Correction amount δ=Min((Bk×(1/ε)×EdgeLevel_{—}Lk, 255−Lk)
Bk′=Bk−δ×ε
Lk′=Lk+δ

Finally, the printer-γ correcting unit 104 performs printer γ correction on the CMY signal output from the color converting unit 101 and the Bk and Lk signals output from the Bk/Lk correcting unit 133, and the halftone processing unit 105 performs a halftone process thereto, and sends the resultant signals to the output engine 106 to output an image. It is to be noted that the Bk/Lk separating unit 804 of the color converting unit 101 uses the separation table in FIG. 4 as in the first embodiment.

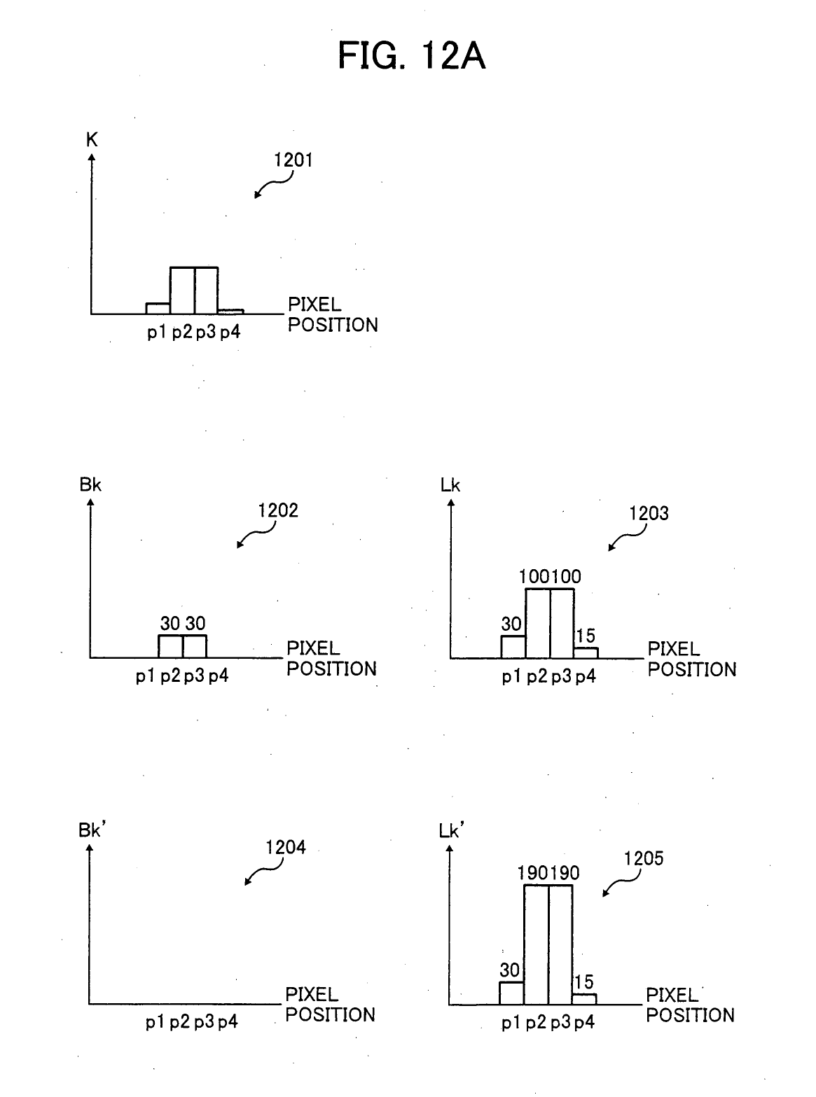

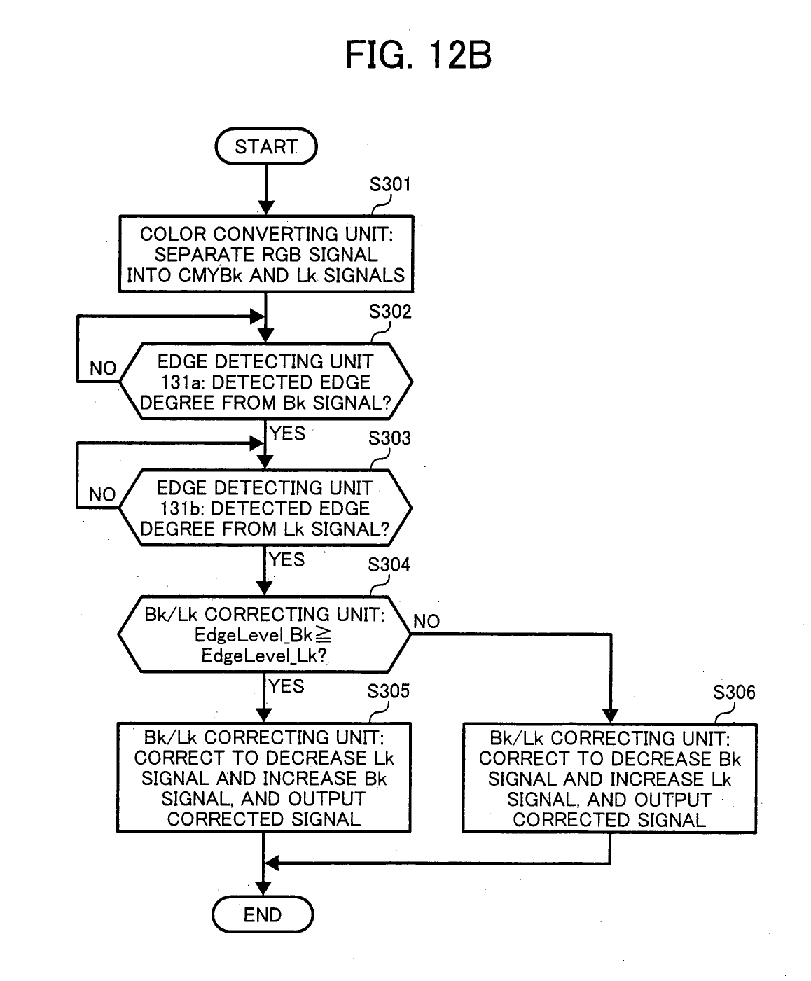

FIG. 12A is an explanatory diagram of a correction operation for the Bk signal and the Lk signal in the Bk/Lk correcting unit 133 in the image processing apparatus according to the third embodiment. With reference to FIG. 6A and FIG. 12A, how to correct the Bk signal and the Lk signal in the third embodiment is explained.

As in the explanation according to the first embodiment, FIG. 6A depicts a case that a high density line image having a width of approximately 2 dots to 3 dots is input. It is apparent in the case of FIG. 6A that the edge level detected from the Bk signal as indicated by the graph 602 in FIG. 6A becomes greater than the edge level detected from the Lk signal as indicated by the graph 603 in FIG. 6A. Therefore, correction for EdgeLevel_Bk<EdgeLevel_Lk is executed. With EdgeLevel_Bk=1, values of the corrected Bk signal and the Lk signal become as indicated in graphs 604 and 605 in FIG. 6A.

FIG. 12A depicts a case that a low density line image having a width of approximately 2 dots to 3 dots is input, and the Bk signal and the Lk signal output from the color converting unit 101 both have values at the pixel positions p2, p3 while only the Lk signal has a value at the pixel positions p1, p4. In this case, the edge level detected from the Lk signal (the graph 1203 in FIG. 12A) becomes greater than the edge level detected from the Bk signal (the graph 1202 in FIG. 12A). Therefore, correction for EdgeLevel_Bk<EdgeLevel_Lk is executed. With EdgeLevel_Lk=1, values of the corrected Bk signal and Lk signal become as indicated in graphs 1204 and 1205 in FIG. 12A.

FIG. 12B is a flowchart of an image processing procedure in the third embodiment. First, the color converting unit 101 separates the RGB signal to the CMYBk and Lk signals. At this time, the black-color generating unit 802 generates black color using the table shown in FIG. 3B, and the Bk/Lk separating unit 804 separates the K signal into the Bk signal and the Lk signal (step S301).

When an edge detecting unit 131 a is in an edge detection state for the separated Bk and Lk signals (step S302), and detects an edge from the Bk signal, and an edge detecting unit 131b is likewise in an edge detection state (step S303) and detects an edge from the Lk signal (step S303: Yes), the Bk/Lk correcting unit 133 compares both edge levels with each other. That is, the Bk/Lk correcting unit 133 determines if EdgeLevel_Bk≧EdgeLevel_Lk (step S304), and determines that the edge level of Bk is higher than the edge level of Lk when the inequality sign is satisfied (step S304: Yes).

The Bk/Lk correcting unit 133 performs correction so as to decrease the Lk signal and increase the Bk signal, and outputs the signals (step S305). When the inequality sign is not satisfied, the Bk/Lk correcting unit 133 determines that the edge level of Bk is lower than the edge level of Lk (step S304: No). The Bk/Lk correcting unit 133 performs correction such as to decrease the Bk signal and increase the Lk signal, and outputs the signals (step S306).

In this manner, a high density line image can be formed using only the Bk toner, and a low density line image can be formed using only the Lk toner, so that even when print misalignment occurs between a Bk print and an Lk print, deterioration of sharpness of the image caused by print misalignment can be prevented.

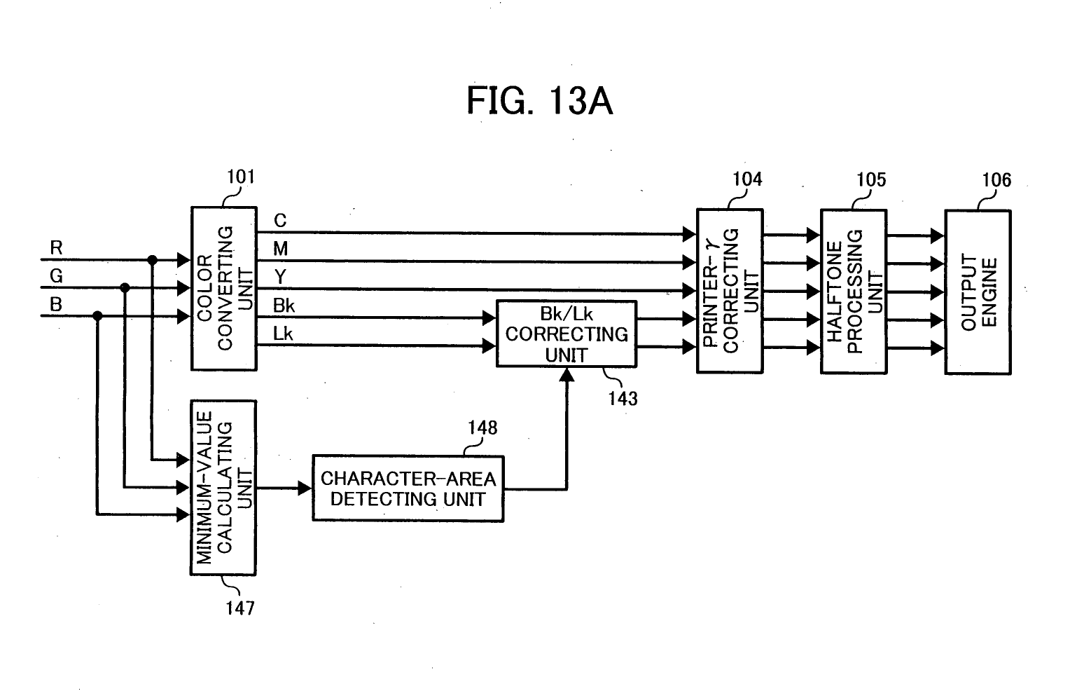

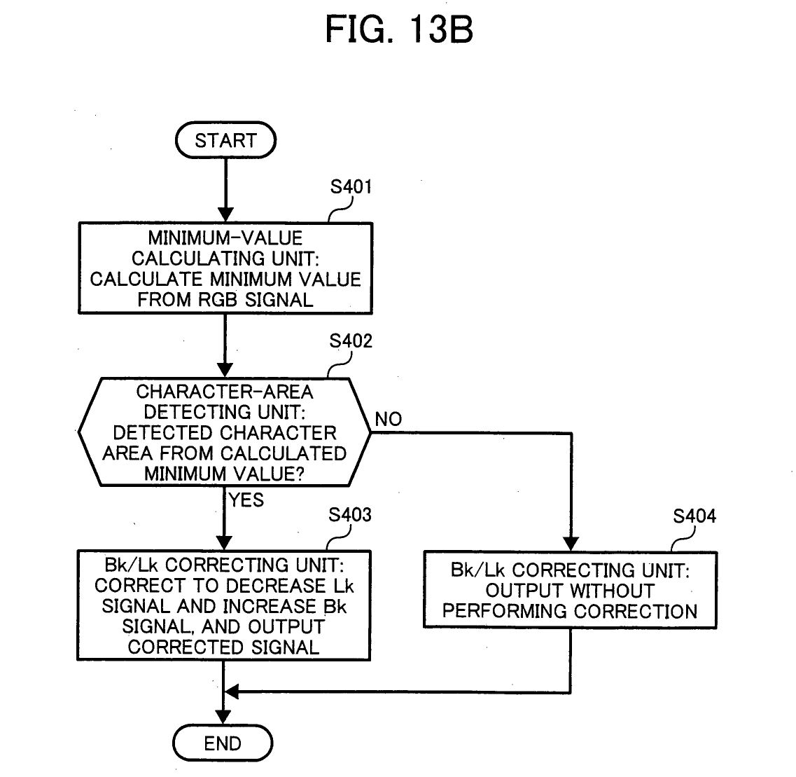

FIG. 13A is a functional block diagram of an image processing apparatus according to the fourth embodiment. The image processing apparatus according to the fourth embodiment includes a minimum-value calculating unit 147 and a character-area detecting unit 148. The fourth embodiment differs from the first embodiment in that a Bk/Lk correcting unit 143 performs correction on the Bk signal and the Lk signal using the result of detecting a character area in the character-area detecting unit 148.

The minimum-value calculating unit 147 calculates a minimum value of the RGB signal before color conversion. The character-area detecting unit 148 then detects a character area with respect to the minimum value of the RGB signal calculated by the minimum-value calculating unit 147. A publicly known technique as described in the specification of Japanese Patent No. 2968277, for example, can be used as the character area detecting method. For example, a signal can be binarized to black pixels/white pixels, linkage of black pixels or white pixels can be detected through pattern matching, and a character area can be detected from the number of the linked black pixels or white pixels.

The Bk/Lk correcting unit 143 corrects the Bk signal and the Lk signal for the detected character area using equations similar to those according to the first embodiment. Finally, the CMY signal from the color converting unit 101, and the Bk signal and the Lk signal from the Bk/Lk correcting unit 143 are subject to a y process by the printer-y correcting unit 104, and are subject to a halftone process by the halftone processing unit 105, before the signals are output to the output engine 106 to output an image.

FIG. 13B is a flowchart of an image processing procedure in the fourth embodiment. The minimum-value calculating unit 147 calculates the minimum value of the RGB signal from the input RGB signal (step S401). The character-area detecting unit 148 detects a character area from the calculated minimum value (step S402). When the character-area detecting unit 148 detects a character (step S402: Yes), the Bk/Lk correcting unit 143 performs correction so as to decrease the Lk signal in the Bk signal and the Lk signal separated from the CMYBk and Lk signals by the color converting unit 101 and increase the Bk signal, and outputs the signals (step S403).

The Bk/Lk correcting unit 143 can form the image of a character area using only the Bk toner by performing a correction process similar to that according to the first embodiment, so that even when print misalignment occurs between a Bk print and an Lk print, deterioration of sharpness can be prevented.

The fourth embodiment differs from the fist embodiment in that a character area from the signals is detected before color conversion. Although not shown in FIG. 13A, an MTF correction process is performed on the RGB signal input from the scanner, and detection of the character area and changing the correction parameter between a character area and a non-character area are performed generally. If the Bk/Lk correcting unit 143 is configured to correct a character area as in the fourth embodiment, the MTF correcting unit (not shown) and the Bk/Lk correcting unit 143 can share the character-area detecting unit 148, which brings about an effect of being able to suppress increase of the hardware scale.

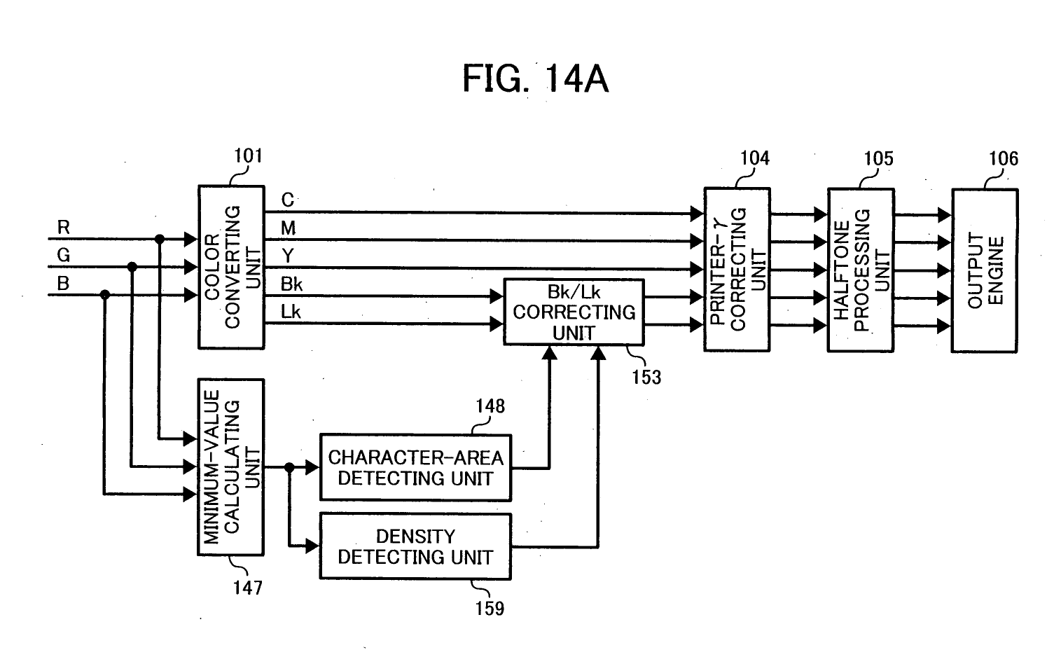

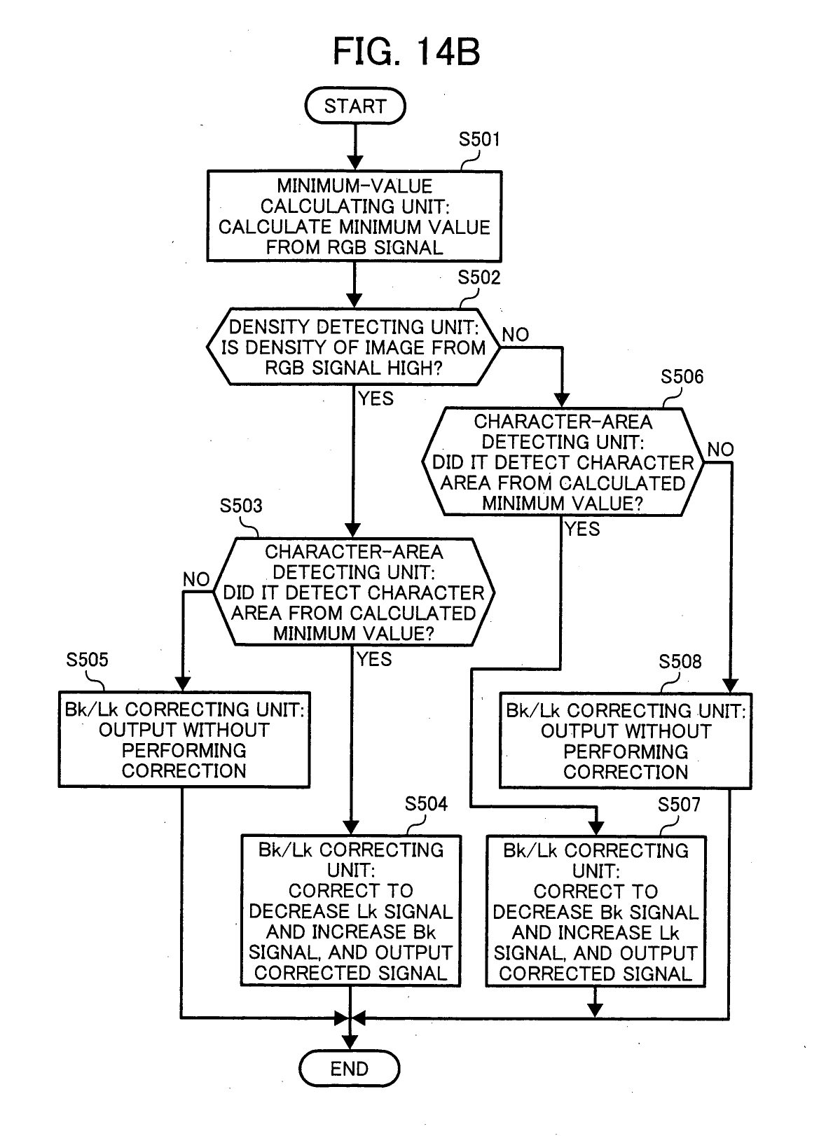

FIG. 14A is a functional block diagram of an image processing apparatus according to the fifth embodiment. The image processing apparatus according to the fifth embodiment differs from that of the fourth embodiment in that the image processing apparatus includes a density detecting unit 159. The image processing apparatus also differs in the function of a Bk/Lk correcting unit 153.

The minimum-value calculating unit 147 is the same as that of the fourth embodiment in that the character-area detecting unit 148 detects a character area with respect to the signal from the minimum-value calculating unit 147. At the same time, the density detecting unit 159 determines if the detected area has a low density or a high density with respect to the signal from the minimum-value calculating unit 147. Specifically, a maximum value in the area of 5×5 pixels around a pixel of interest is calculated, and the image is determined as having a high density when the maximum value is equal to or greater than a predetermined threshold, and is determined as having a low density when the maximum value is less than the predetermined threshold. The determination of whether the image has a low density or a high density in the density detecting unit 159 can be performed by other methods.

The Bk/Lk correcting unit 153 calculates a correction amount δ given by the following equations according to the result of determination in the density detecting unit 159 with respect to the detected character area, corrects the Bk signal and the Lk signal using the correction amount δ, and outputs the signals.

When it is a character area having a high density, correction is performed as follows.
Correction amount δ=Min(Lk×ε, 255−Bk)
Bk′=Bk+δ
Lk′=Lk−δ×(1/ε)=0

When it is a character area having a low density, correction is performed as follows.
Correction amount δ=Min(Bk×(1/ε), 255−Lk)
Bk′=Bk−δ×ε
Lk′=Lk+δ

Finally, the printer-γ correcting unit 104 performs γ correction on the CMY signal output from the color converting unit 101 and the Bk and Lk signals output from the Bk/Lk correcting unit 153, and the halftone processing unit 105 performs a halftone process thereto, and sends the resultant signals to the output engine 106 to output an image.

In the fifth embodiment, correction is performed on a character area having a high density as shown in FIG. 6A, and correction is performed on a character area having a low density as shown in FIG. 12A. FIG. 6A and FIG. 12A will not be described below since they have already been explained in the foregoing description of the third embodiment.

FIG. 14B is a flowchart of an image processing procedure in the fifth embodiment. The minimum-value calculating unit 147 calculates the minimum value of the RGB signal from the input RGB signal (step S501). The density detecting unit 159 detects from the RGB signal if the density of an image is high (step S502). When the density detecting unit 159 detects that the density of the image is high (step S502: Yes), the character-area detecting unit 148 detects a character area from the calculated minimum value (step S503).

When the character-area detecting unit 148 detects a character area (step S503: Yes), in which case the image is a character having a high density, the Bk/Lk correcting unit 153 performs correction to decrease the Lk signal and increase the Bk signal, and outputs the signals (step S504). When the character-area detecting unit 148 does not detect a character area (step S503: No), the Bk/Lk correcting unit 153 directly sends the separated signals converted by the color converting unit 101 to the output engine 106 without performing correction (step S505).

When the density detecting unit 159 does not detect that the density of the image is high (step S502: No), the character-area detecting unit 148 detects a character area from the calculated minimum value (step S506). When the character-area detecting unit 148 detects a character area (step S506: Yes), in which case the image is a character having a low density, the Bk/Lk correcting unit 153 performs correction to decrease the Bk signal and increase the Lk signal, and outputs the signals (step S507). When the character-area detecting unit 148 does not detect a character area (step S506: No), the Bk/Lk correcting unit 153 directly sends the separated signals converted by the color converting unit 101 to the output engine 106 without performing correction (step S508).

In this manner, the image processing apparatus according to the fifth embodiment can form the image of a high density character area using only the Bk toner, and the image of a low density character area using only the Lk toner, so that even when print misalignment occurs between a Bk print and an Lk print, deterioration of image sharpness can be prevented. For an area other than a character area, the Bk signal and the Lk signal are output directly without being subject to correction with a Bk print and an Lk print, so that a photograph or the like is output naturally and beautifully.

With the image processing apparatus equipped with a scanner as in the fourth embodiment, the MTF correcting unit (not shown) and the Bk/Lk correcting unit 153 can share the character-area detecting unit 148, thereby suppressing increase of the hardware scale.

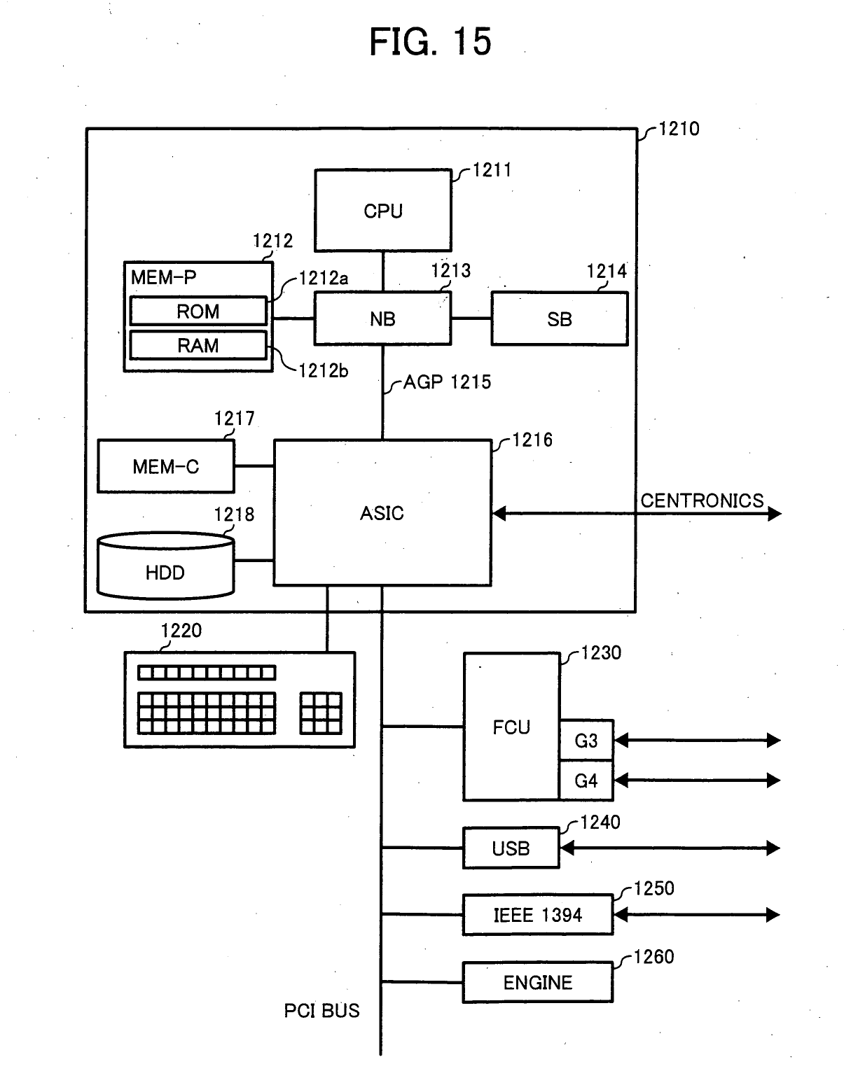

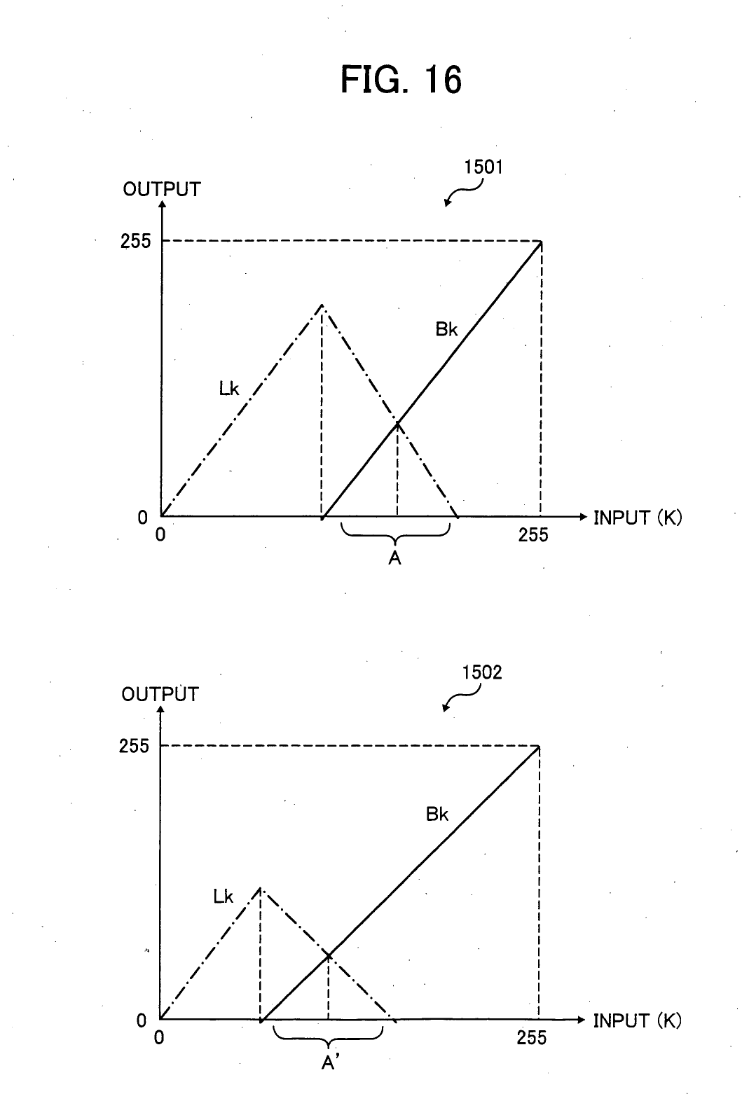

FIG. 15 is a block diagram of the hardware configuration of the image processing apparatus according to the embodiments. A multifunction product (MFP) shown in FIG. 15 is configured as one having multiple functions, such as a facsimile and a scanner. As shown in FIG. 15, the MFP includes a controller 1210 and an engine 1260 connected together by a peripheral component interconnect (PCI) bus. The controller 1210 controls inputs from an FCU interface (I/F) 1230 and an operation display unit 1220, such as the general control of the MFP, display control, various controls and image processing control. The image processing apparatus according to the embodiments explained above is included in the controller 1210. The engine 1260 is an image processing engine or the like connectable to the PCI bus, and includes an image processing section that performs, for example, error diffusion and gamma conversion on acquired image data.

The controller 1210 includes a central processing unit (CPU) 1211, a north bridge (NB) 1213, a system memory (MEM-P) 1212, a south bridge (SB) 1214, a local memory (MEM-C) 1217, an application specific integrated circuit (ASIC) 1216, and a hard disk drive (HDD) 1218. The NB 1213 and the ASIC 1216 are connected together via an accelerated-graphics-port (AGP) bus 1215. The MEM-P 1212 includes a read only memory (ROM) 1212a, and a random access memory (RAM) 1212b.

The CPU 1211 controls the MFP, includes a chip set including the NB 1213, the MEM-P 1212, and the SB 1214, and is connected to other devices via the chip set.

The NB 1213 is a bridge for connecting the CPU 1211 to the MEM-P 1212, the SB 1214, and the AGP 1215, and includes a memory controller that controls reading and writing to the MEM-P 1212, a PCI master, and an AGP target.

The MEM-P 1212 is a system memory that is used as a storage memory of a program and data, and as a development memory of a program and data, and includes of the ROM 1212a and the RAM 1212b. The ROM 1212a is used as a storage memory of a program and data. The RAM 1212b is a writable and readable memory that is used as a development memory of a program and data, and as an image drawing memory at the time of image processing.

The SB 1214 is a bridge that connects the NB 1213, the PCI device, and peripheral devices. The SB 1214 is connected to the NB 1213 via the PCI bus. The PCI bus is also connected to the FCU I/F 1230 and the like.

The ASIC 1216 is an integrated circuit (IC) for multimedia information processing including a hardware element for multimedia information processing, and functions as a bridge that connects the AGP 1215, the PCI bus, the HDD 1218, and the MEM-C 1217.

The ASIC 1216 is connected to a universal serial bus (USB) 1240 and the Instituted of Electrical and Electronics Engineers (IEEE) 1394 interface 1250, via the PCI bus, among a PCI target and an AGP master, an arbiter (ARB) that forms a core of the ASIC 1216, the memory controller that controls the MEM-C 1217, a plurality of direct memory access controllers (DMAC) that rotate image data based on a hardware logic and the like, and the engine 1260.

The MEM-C 1217 is a local memory that is used as a transmission image buffer and a code buffer. The HDD 1218 is a storage that stores image data, programs, font data, and forms.

The AGP 1215 is a bus interface for a graphics accelerator card that is proposed to increase the graphic processing speed. The AGP 1215 directly accesses the MEM-P 1212 in high throughput, thereby increasing the speed of the graphics accelerator card.

The operation display unit 1220 (keyboard) that is connected to the ASIC 1216 receives an operation input from an operator, and transmits received operation input information to the ASIC 1216.

An image processing program to be executed by the MFP according to the present embodiment is provided by being installed in a ROM or the like in advance.

The image processing program to be executed by the MFP according to the present embodiment can be provided by being recorded on a computer-readable recording medium such as a CD-ROM, a flexible disc (FD), a CD-recordable (CD-R), and a digital versatile disk (DVD), in an installable format file or an executable format file.

The image processing program to be executed by the MFP according to the present embodiment can be stored in a computer connected to a network such as the Internet, and can be downloaded via the network. The image processing program to be executed by the MFP according to the embodiment can be provided or distributed via the network such as the Internet.

The image processing program that is executed by the MFP of the embodiment takes module configurations including the components mentioned above (the color converting unit 101, the edge detecting unit 102, the Bk/Lk correcting unit 103, the printer-y correcting unit 104, the halftone processing unit 105 or the like). As the CPU (processor), as actual hardware, reads and executes the image processing program from a read only memory (ROM), each of the individual component is loaded onto the main memory so that the color converting unit 101, the edge detecting unit 102, the Bk/Lk correcting unit 103, the printer-y correcting unit 104, the halftone processing unit 105 and the like are generated in the main memory.

The embodiments and the modification explained above are only exemplary for explaining the present invention, and the invention is not limited to these specific examples.

According to an embodiment of the present invention, the ratio of grayscale color materials in use can be appropriately controlled according to the feature of an image by performing correction according to the feature of the image that is detected from dark and light color signals generated by the color converting process.

Furthermore, according to an embodiment of the present invention, the ratio of grayscale color materials in use can be appropriately controlled at the edge portion of an image by correcting dark and light color signals after color conversion according to edge information as the feature of the image.

Moreover, according to an embodiment of the present invention, an edge is detected from a signal corresponding to a dense color material after color conversion, and the image of an edge portion of a high density is formed using a large amount of dense color materials, so that even when print misalignment occurs, deterioration of sharpness of a character/line image can be prevented.

Furthermore, according to an embodiment of the present invention, an edge is detected from a signal corresponding to a light color material after color conversion, and the image of an edge portion is formed using a large amount of dense color materials, so that even when print misalignment occurs, deterioration of sharpness of a character/line image can be prevented.

Moreover, according to an embodiment of the present invention, an edge is detected from respective signals corresponding to grayscale color materials after color conversion, and the ratio of grayscale color materials in use can be appropriately controlled according to edge information of the dark and light color signals, so that an image can be formed by appropriately controlling the ratio of grayscale color materials according to the density of the edge portion. Therefore, even when print misalignment occurs, deterioration of sharpness of a character/line image can be prevented.

Furthermore, according to an embodiment of the present invention, as the image of an edge portion of a low density is formed using a large amount of light color materials, a character/line image of a low density can be reproduced with a high image quality, so that even when print misalignment occurs, deterioration of image sharpness can be prevented.

Moreover, according to an embodiment of the present invention, the image of an edge portion of a high density is formed using a large amount of dense color materials, so that even when print misalignment occurs, deterioration of sharpness of a character/line image of a high density can be prevented.

Furthermore, according to an embodiment of the present invention, the ratio of grayscale color materials in use can be appropriately controlled according to the feature of an image by detecting the feature of an image from image data, and correcting color signals corresponding to grayscale color materials after color conversion based on the feature of the image detected from the image data.

Moreover, according to an embodiment of the present invention, the ratio of grayscale color materials in use can be appropriately controlled with respect to a character area by detecting character-area information from image data, and correcting color signals corresponding to grayscale color materials after color conversion based on the character-area information detected from the image data.

Furthermore, according to an embodiment of the present invention, the image of a character area is formed using a large amount of dense color materials, so that even when print misalignment occurs, deterioration of sharpness of a character/line image can be prevented.

Moreover, according to an embodiment of the present invention, the ratio of grayscale color materials in use can be appropriately controlled in a character area by correcting dark and light color signals after color conversion based on the character-area information detected from image data.

Furthermore, according to an embodiment of the present invention, as the image of a character area of a low density is formed using a large amount of light color materials, the image of a character area of a high density is formed using a large amount of dense color materials, a character/line image can be reproduced with a high image quality, so that even when print misalignment occurs, deterioration of image sharpness can be prevented.

Moreover, according to an embodiment of the present invention, the ratio of grayscale color materials in use can be appropriately controlled with respect to an edge area by detecting edge area information from image data, and correcting color signals corresponding to grayscale color materials after color conversion based on the detected edge area information.

Furthermore, according to an embodiment of the present invention, the image of an edge area of a high density is formed using a large amount of dense color materials, so that even when print misalignment occurs, deterioration of sharpness of an edge/line image can be prevented.

Moreover, according to an embodiment of the present invention, the ratio of grayscale color materials in use can be appropriately controlled in an edge area of an image by correcting dark and light color signals after color conversion based on edge area information detected from image data.

Furthermore, according to an embodiment of the present invention, as the image of an edge area of a low density is formed using a large amount of light color materials, the image of an edge area of a high density is formed using a large amount of dense color materials, an edge/line image can be reproduced with a high image quality, so that even when print misalignment occurs, deterioration of image sharpness can be prevented.

Moreover, according to an embodiment of the present invention, the ratio of grayscale color materials in use can be appropriately controlled according to the feature of an image by performing correction according to the feature of the image that is detected from dark and light color signals generated in the color converting process.

Furthermore, according to an embodiment of the present invention, the ratio of grayscale color materials in use can be appropriately controlled at the edge portion of an image by correcting dark and light color signals after color conversion according to edge information as the feature of the image.

Moreover, according to an embodiment of the present invention, an edge is detected from a signal corresponding to a dense color material after color conversion, and the image of an edge portion of a high density is formed using a large amount of dense color materials, so that even when print misalignment occurs, deterioration of sharpness of a character/line image can be prevented.

Furthermore, according to an embodiment of the present invention, an edge is detected from a signal corresponding to a light color material after color conversion, and the image of an edge portion is formed using a large amount of dense color materials, so that even when print misalignment occurs, deterioration of sharpness of a character/line image can be prevented.

Moreover, according to an embodiment of the present invention, an edge is detected from signals respectively corresponding to grayscale color materials after color conversion, and the ratio of grayscale color materials in use can be appropriately controlled according to edge information of the dark and light color signals, so that an image can be formed by appropriately controlling the ratio of grayscale color materials according to the density of the edge portion. Even when print misalignment occurs, therefore, deterioration of sharpness of a character/line image can be prevented.

Furthermore, according to an embodiment of the present invention, as the image of an edge portion of a low density is formed using a large amount of light color materials, a character/line image of a low density can be reproduced with a high image quality, so that even when print misalignment occurs, deterioration of image sharpness can be prevented.

Moreover, according to an embodiment of the present invention, the image of an edge portion of a high density is formed using a large amount of dense color materials, so that even when print misalignment occurs, deterioration of sharpness of a character/line image of a high density can be prevented.

Furthermore, according to an embodiment of the present invention, the ratio of grayscale color materials in use can be appropriately controlled according to the feature of an image by detecting the feature of an image from image data, and correcting color signals corresponding to grayscale color materials after color conversion based on the feature of the image detected from the image data.

Moreover, according to an embodiment of the present invention, the ratio of grayscale color materials in use can be appropriately controlled with respect to a character area by detecting character-area information from image data, and correcting color signals corresponding to grayscale color materials after color conversion based on the character-area information detected from the image data.

Furthermore, according to an embodiment of the present invention, the image of a character area is formed using a large amount of dense color materials, so that even when print misalignment occurs, deterioration of sharpness of a character/line image can be prevented.

Moreover, according to an embodiment of the present invention, the ratio of grayscale color materials in use can be appropriately controlled in a character area by correcting dark and light color signals after color conversion based on the character-area information detected from image data.

Furthermore, according to an embodiment of the present invention, as the image of a character area of a low density is formed using a large amount of light color materials, the image of a character area of a high density is formed using a large amount of dense color materials, a character/line image can be reproduced with a high image quality, so that even when print misalignment occurs, deterioration of image sharpness can be prevented.

Moreover, according to an embodiment of the present invention, the ratio of grayscale color materials in use can be appropriately controlled with respect to an edge area by detecting edge area information from image data, and correcting color signals corresponding to grayscale color materials after color conversion based on the detected edge area information.

Furthermore, according to an embodiment of the present invention, the image of an edge area of a high density is formed using a large amount of dense color materials, so that even when print misalignment occurs, deterioration of sharpness of an edge/line image can be prevented.

Moreover, according to an embodiment of the present invention, the ratio of grayscale color materials in use can be appropriately controlled in an edge area of an image by correcting dark and light color signals after color conversion based on edge area information detected from image data.

Furthermore, according to an embodiment of the present invention, as the image of an edge area of a low density is formed using a large amount of light color materials, the image of an edge area of a high density is formed using a large amount of dense color materials, an edge/line image can be reproduced with a high image quality, so that even when print misalignment occurs, deterioration of image sharpness can be prevented.

Moreover, according to an embodiment of the present invention, there is provided a program that can make a computer execute the image processing method according to the invention.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. An image processing apparatus that generates color signals corresponding to respective color materials for forming a color image using a grayscale color material for at least one of a plurality of colors based on image data, the image processing apparatus comprising:
a color converting unit to generate a color signal corresponding to each of the color materials from the image data;
a feature detecting unit to detect a feature of an image from the color signal corresponding to the grayscale color material generated by the color converting unit; and
a correcting unit to correct a color signal corresponding to the grayscale color material based on the feature of the image detected by the feature detecting unit.

2. The image processing apparatus according to claim 1, wherein
the feature detecting unit detects edge information as the feature of the image.

3. The image processing apparatus according to claim 2, wherein
the feature detecting unit detects the edge information from a color signal corresponding to a dense color material from among the grayscale color materials, and
the correcting unit corrects the color signal based on the edge information by decreasing a color signal corresponding to a light color material and increasing the color signal corresponding to the dense color material.

4. The image processing apparatus according to claim 2, wherein
the feature detecting unit detects the edge information from a color signal corresponding to a light color material from among the grayscale color materials, and
the correcting unit corrects the color signal based on the edge information by decreasing the color signal corresponding to the light color material and increasing a color signal corresponding to a dense color material.

5. The image processing apparatus according to claim 2, wherein
the feature detecting unit detects information on edge levels from respective color signals corresponding to the grayscale color materials, and
the correcting unit corrects the color signal corresponding to the grayscale color material by comparing the edge levels detected by the feature detecting unit.

6. The image processing apparatus according to claim 5, wherein
when the edge level of a color signal corresponding to a light color signal is determined to be greater than the edge level of a color signal corresponding to a dense color material, the correcting unit corrects the color signal by increasing the color signal corresponding to the light color material and decreasing the color signal corresponding to the dense color material.

7. The image processing apparatus according to claim 5, wherein
when the edge level of a color signal corresponding to a dense color material is determined to be greater than the edge level of a color signal corresponding to a light color material, the correcting unit corrects the color signal by increasing the color signal corresponding to the dense color material and decreasing the color signal corresponding to the light color material.

8. An image processing apparatus that generates color signals corresponding to respective color materials for forming a color image using a grayscale color material for at least one of a plurality of colors based on image data, the image processing apparatus comprising:
a feature detecting unit to detect a feature of an image from the image data;
a color converting unit to generate a color signal corresponding to each of the color materials from the image data; and
a correcting unit to correct a color signal corresponding to a grayscale color material generated by the color converting unit, based on the feature of the image detected by the feature detecting unit.

9. The image processing apparatus according to claim 8, wherein
the feature detecting unit detects a character area as the feature of the image.

10. The image processing apparatus according to claim 9, wherein
the correcting unit corrects the color signal by increasing a color signal corresponding to a dense color material and decreasing a color signal corresponding to a light color material with respect to the character area detected by the feature detecting unit.

11. The image processing apparatus according to claim 10, wherein
the feature detecting unit further detects a density of the detected character area as the feature of the image.

12. The image processing apparatus according to claim 11, wherein
for a character area where the density detected by the feature detecting unit is equal to or greater than a predetermined density, the correcting unit corrects the color signal by increasing the color signal corresponding to the dense color material and decreasing the color signal corresponding to the light color material, and
for a character area where the density detected by the feature detecting unit is less than the predetermined density, the correcting unit corrects the color signal by increasing the color signal corresponding to the light color material and decreasing the color signal corresponding to the dense color material.

13. The image processing apparatus according to claim 8, wherein
the feature detecting unit detects edge information as the feature of the image.

14. The image processing apparatus according to claim 13, wherein
the correcting unit corrects the color signal by increasing a color signal corresponding to a dense color material and decreasing a color signal corresponding to a light color material with respect to the edge detected by the feature detecting unit.

15. The image processing apparatus according to claim 14, wherein
the feature detecting unit further detects a density of the detected edge as the feature of the image.

16. The image processing apparatus according to claim 15, wherein
for an edge where the density detected by the feature detecting unit is equal to or greater than a predetermined density, the correcting unit corrects the color signal by increasing the color signal corresponding to the dense color material and decreasing the color signal corresponding to the light color material, and
for an edge where the density detected by the feature detecting unit is less than the predetermined density, the correcting unit corrects the color signal by increasing the color signal corresponding to the light color material and decreasing the color signal corresponding to the dense color material.

17. An image processing method of generating color signals corresponding to respective color materials for forming a color image using a grayscale color material for at least one of a plurality of colors based on image data, the image processing method comprising:
generating a color signal corresponding to each of the color materials from the image data;
detecting a feature of an image from the generated color signal corresponding to the grayscale color material generated at the generating; and
correcting a color signal corresponding to the grayscale color material based on the detected feature of the image.

18. The image processing method according to claim 17, wherein
detecting the feature includes detecting edge information as the feature of the image.

19. The image processing method according to claim 18, wherein
detecting the feature includes detecting the edge information from a color signal corresponding to a dense color material from among the grayscale color materials, and
correcting the color signal includes correcting the color signal based on the edge information by decreasing a color signal corresponding to a light color material and increasing the color signal corresponding to the dense color material.

20. The image processing method according to claim 18, wherein
detecting the feature includes detecting the edge information from a color signal corresponding to a light color material from among the grayscale color materials, and
correcting the color signal includes correcting the color signal based on the edge information by decreasing the color signal corresponding to the light color material and increasing a color signal corresponding to a dense color material.
